(19) United States
(12) Patent Application Publication
(10) Pub. No.: US 2016/0251749 A1
(43) Pub. Date: Sep. 1, 2016

(54) Oxidized Layer and Light Metal Layer on Substrate

(71) Applicant: HEWLETT PACKARD DEVELOPMENT COMPANY, L.P., Houston, TX (US)

(72) Inventors: KUAN-TING WU, TAIPEI CITY (TW); YU-CHUAN KANG, Tapei City (TW); CHUNG-HUNG HUANG, Tapei City (TW)

(21) Appl. No.: 15/026,361

(22) PCT Filed: Nov. 21, 2013
(86) PCT No.: PCT/US13/71158

§ 371 Date: Mar. 31, 2016

(51) Int. Cl. C23C 14/20; C23C 14/58; C23C 14/34

(52) U.S. Cl. CPC C23C 14/20; C23C 14/34; C23C 14/5853

(57) ABSTRACT

A material may include a substrate, a light metal layer on the substrate and an oxidized layer on the light metal layer. In some cases, the substrate may include a fiber material and a thermoplastic binding polymer. In other cases, the substrate may include a light metal and a fiber material.

### BACKGROUND

Composite materials are materials made from t two or more constituent materials with different physical properties. When combined, the constituent materials produce a material with characteristics different from the individual components. For example, a laminate material may comprise a plurality of different material layers. As another example, a reinforced material may comprise a mixture of different material. Examples of reinforced materials may include fiber-reinforced plastics (FRPs), such as carbon fiber-reinforced plastics (CFRPs), and metal matrix composites (MMCs), such as metal-infiltrated carbon fiber.

### BRIEF DESCRIPTION OF THE DRAWINGS

Certain examples are described in the following detailed description and in reference to the drawings, in which:

FIG. 1 illustrates an example material including a fiber layer, a metal layer, and an anodized layer; and

FIG. 2 illustrates an example method of creating a material having a substrate, a light metal layer, and an anodized layer.

### DETAILED DESCRIPTION OF SPECIFIC EXAMPLES

Composite materials, such as laminates, FRPs, and MMCs may be useful materials for consumer products such as electronics devices. For example, their high strength-to-weight ratios may make them suitable materials for electronic device housings. However, they may have a particular look and feel that may be undesired by some consumers. For example, CFRP may have characteristics such as a plastic texture created by the plastic matrix and a black appearance with visible fabric weave created by the carbon fiber fabric reinforcement.

Some implementations of the disclosed technology may provide a composite material having a hard, metallic, and colorable coating. In some implementations, the composite material may comprise a light metal, carbon fiber, or light metal infiltrated substrate having an oxidized coating. A light metal may be aluminum, titanium, magnesium or an alloy having aluminum, titanium, magnesium or combination thereof as a primary constituent. In some cases, the composite material may be manufactured by depositing a light metal coating onto a substrate using physical vapor deposition. The light metal coating may be oxidized to form an oxidized coating on the metal coating. In some implementations, the light metal coating may be oxidized by anodization or micro-arc oxidation. In some examples, the substrate may comprise a fiber material and may be infiltrated with a plastic matrix after the formation of the oxidized coating.

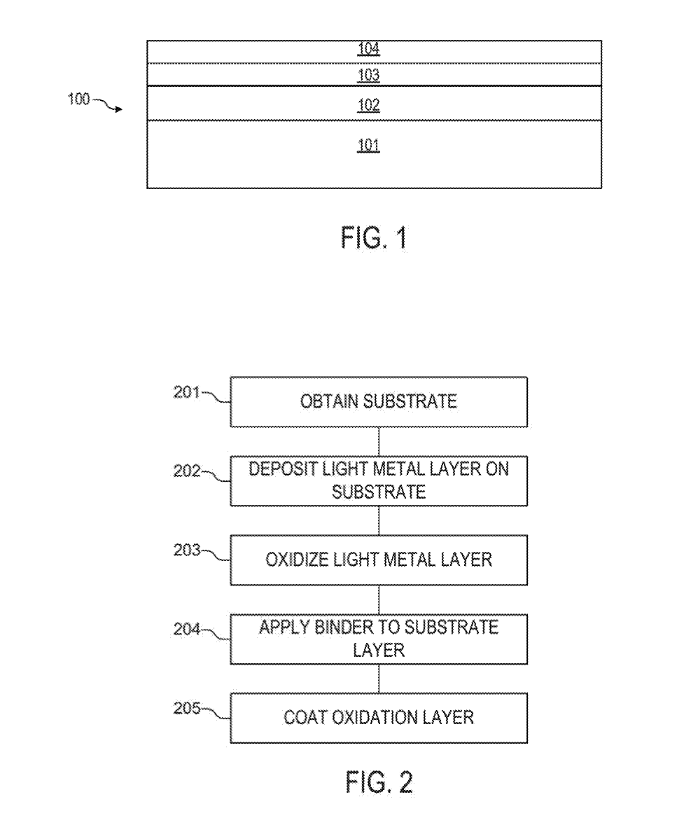

FIG. 1 illustrates an example material 100 including a substrate 101 a light metal layer 102, and an oxidized layer 103. In some implementations, the example material 100 constitute articles such as housings for electronics, including portable devices such as tablets, smartphones, and laptop and notebook computers.

The example material 100 may include a substrate 101. The substrate 101 may have a variety of thicknesses depending on its application. For example, when used in the manufacture of a laptop housing, the substrate 101 may have a thickness on the order of a few millimeters. For example, the substrate 101 may have a thickness between 0.1-12 mm.

In some implementations, the substrate 101 may be a fiber layer 101. The fiber layer 101 may include a fiber material. In some implementations, the fiber material may include carbon fiber, carbon nanotubes, glass fiber, ceramic fiber, silicon carbide fiber, aramid fiber, metal fiber, or combinations thereof. In a particular implementation, the fiber material may comprise carbon fiber, such as polyacrylonitrile-derived carbon fiber (PAN carbon fiber). In further implementations, the fiber material may include coated or uncoated fibers, and continuous or discontinuous fibers. In still further implementations, the fiber material may be in woven or non-woven form. For example, the fiber material may be a woven PAN carbon fiber.

In some implementations, the fiber layer 101 may further include a binding polymer. For example, the fiber layer 101 may include a matrix of the binding polymer reinforced by the fiber material. In various mpiementations, the binding polymer may include thermoplastics such as vinyl ester, polyester, polyacrylate polymers, cyclic olefin copolymer, polycarbonate, thermoplastic polyurethane or nylon. For example, the binding polymer may be a polyacrylate polymer. In other implementations, the binding polymer may include thermosets such as epoxy or polyurethane resins; and ultraviolet light (UV) curable resins. For example, the binding polymer may be an epoxy resin.

In some implementations, the fiber layer 101 may further include a light metal infiltrating the fiber material. In some cases, the light metal may comprise aluminum, aluminum alloys, magnesium, magnesium alloys, titanium, or titanium alloys. For example, the light metal may comprise magnesium alloyed with lithium and zinc (LZ), such as LZ91, or magnesium alloyed with aluminum and zinc (AZ), such as AZ31 or AZ91. As another example, the light metal may comprise pure aluminum, or aluminum alloyed with magnesium, such as a 5000 or 6000 series aluminum alloy.

The example material 100 may include a light metal layer 102 on the substrate 101. For example, the light metal nay include aluminum, aluminum alloy, magnesium, magnesium alloy, titanium, or titanium alloy. In some implementations, the light metal layer 102 is composed of aluminum or an aluminum alloy, such as a 5000 or 6000 series aluminum alloy. In other implementations, the light metal layer 102 is composed of magnesium or a magnesium alloy. For example, the magnesium alloy may comprise magnesium alloyed with lithium and zinc (LZ), such as LZ91, or magnesium alloyed with aluminum and zinc (LZ), such as AZ31 or AZ91. In some implementations, the light metal layer 102 may provide a metallic feel to the composite material 100 and may serve as a substrate for an oxidized layer 103. In some cases, the light metal layer 102 may have a thickness less than 2 mm.

The example material 100 may also include an oxidized layer 103 on the light metal layer 102. For example, the oxidized layer 103 may be a layer composed of oxides of the metal of light metal layer 102 that is larger than a natural oxide layer that would otherwise occur on light metal layer 102. The oxidized layer 103 may provide a harder surface than the light metal layer 102 or the substrate 101. Accordingly, a material 100 having an oxidized layer 103 may be more scratch resistant than a material lacking such an oxidized layer 103. Additionally, the oxidized layer 103 may include a dye or colorant. In various implementations, the oxidized layer 103 may have varying thickness depending on application.

In some implementations, the oxidized layer 103 may be created using an oxidation process such as anodization or micro-arc oxidation (MAO). In some instances, the oxidized layer 103 may be between 1-50 μm depending on oxidation process and desired characteristics. For example, a thin, transparent oxidized layer 103 may produce iridescence effects, while a thicker oxidized layer 103 may be used to retain dyes.

In some implementations, the oxidized layer 103 is an anodized layer. In such implementations, the oxidized layer 103 may be composed primarily of amorphous forms of oxides of the light metal layer 102. For example, the oxidized layer 103 may be composed of amorphous alumina or titanic. In some implementations, the oxidized layer 103 may be between 1 and 50 μm. For example, the oxidized layer 103 may be produced using a sulfuric acid anodizing process and has a thickness between 3 and 25 μm. In some implementations, the thickness of the oxidized layer 103 may be dependent on the thickness of the light metal layer 102. For example, the anodized layer may be between 10% and 90% as thick as the light metal layer 102. In a particular example, the anodized layer may be between 30% and 70% as thick as the light metal layer 102.

In other implementations, the oxidized layer 103 is a micro-arc oxidized layer. In such implementations, the oxidized layer 103 may include crystalline forms of the oxides of the light metal layer 102. Compared to an oxidized layer created using anodization, an oxidized layer created using MAO may exhibit melting, melt-flow, re-solidification, sintering, and densification. Accordingly, an oxidized layer created using MAO may be less porous than a comparable oxidized layer created using anodization. In such implementations, the oxidized layer 103 may be between 3 and 25 μm. Additionally, in such implementations, oxides may occur in the light metal layer 102 at the interface between the fiber layer 101 and he light metal layer 102. In some implementations, these interfacial oxides may improve the bond strength between the fiber layer 101 and the light metal layer 102. For example, the interfacial oxides may improve the bond strength if the fiber layer 101 includes a light metal infiltrating the fiber layer.

In some implementations, the material 100 may include a coaling 104. For example, the coating 104 may comprise paint, a spray coating, an ultraviolet (UV) light resistant coating, a nanoparticle coating, a fingerprint resistant coating, an anti-bacterial coating. In some implementations, the coating may be applied by painting, dying, spray coating, film lamination, chemical vapor deposition (CVO) or PVD coating, electrophoretic deposition, or using other coating technologies. In some implementations, the coating 104 may be used to apply a color to the material 100. For example, in some cases, If the oxidized layer 103 is applied using MAO, the layer 103 may not satisfactorily retain a dye. As another example, dying the oxidized layer 103 may not produce desired shades or other visual characteristics. Accordingly, in such an example, a coating 104 may be used to color the material 100.

FIG. 2 illustrates an example method of creating a material having a substrate, a light metal layer, and an oxidized layer. For example, the method of FIG. 2 may be used to manufacture the material 100 described with the respect to FIG. 1.

The example method may include block 201. Block 201 may include obtaining a substrate. In some implementations, the substrate may be as described with respect to substrate 101 of FIG. 1. For example, the substrate may include a fiber material as described with respect to fiber layer 101 of FIG. 1. For example, the fiber layer may include woven or unwoven fibers such as carbon fibers, carbon nanotubes, glass fibers, ceramic fibers, silicon carbide fibers, aramid fibers, metal fibers, or combinations thereof.

In some implementations, block 201 may include obtaining a substrate comprising a fiber layer lacking a binding polymer. In other implementations, block 201 may include obtaining a fiber layer having a binding polymer. For example, in some implementations, the fiber layer may be subject to an acid bath during a subsequent anodization process. Accordingly, block 201 may include obtaining a fiber layer having a binding polymer that is resistant to the acid bath. For example, block 201 may include obtaining a fiber layer having a thermosetting or UV curable resin that is resistant to the acid bath.

In some implementations, block 201 may include obtaining a substrate comprising a light metal infiltrating the fiber material. For example, the substrate may comprise a light metal infiltrated carbon fiber substrate. In some cases, the light metal may comprise aluminum, aluminum alloys, magnesium, magnesium alloys, titanium, or titanium alloys. For example, the light metal may comprise magnesium alloyed with lithium and zinc (LZ), such as LZ91, or magnesium alloyed with aluminum and zinc (AZ), such as AZ31 or AZ91. As another example, the light metal may comprise pure aluminum, or aluminum alloyed with magnesium, such as a 5000 or 6000 series aluminum alloy.

The example method may further include block 202. Block 202 may include depositing a light metal layer on the fiber layer. In some implementations, the light metal layer may be as described with respect to light metal layer 102 of FIG. 1. For example, the light metal layer may comprise aluminum, an aluminum alloy, magnesium, a magnesium alloy, titanium or a titanium alloy. In some implementations, depositing the metal layer may comprise applying the metal layer using physical vapor deposition (PVD) In particular implementations, block 202 may include depositing the metal layer inc sputter deposition. For example, the sputtering may include ion-beam sputtering (IBS), reactive sputtering, ion-assisted deposition (IAD), high-target-utilization sputtering, high-power impulse magnetron sputtering (HIPIMS), or gas flow sputtering. In these examples, block 202 may include using a sputter target comprising the metal of the light metal layer.

The example method may also include block 203. Block 203 may comprise oxidizing the light metal layer to form an oxidized layer on the light metal layer. For example, the oxidized layer may be as described with respect to oxidized layer 103 of FIG. 1. In some implementations, block 203 may include anodizing the light metal layer to form an anodized layer on the light metal layer. In other implementations, block 203 may include performing MAO on the light metal layer.

In some implementations, block 203 may include the light metal layer being anodized by placing the bonded substrate and metal layer into a chemical bath and passing an electric current through the bath, causing the surface of the metal layer to oxidize. For example, the chemical bath may include sulfuric acid, chromic acid caustic soda, sodium nitrate, sodium nitrite, trisodium phosphate, orthophosphoric acid, nitric acid, glacial acetic acid, silicic acid, boric acid, phosphoric acid, molybdic acid, vanadic acid, permanganic acid, stannic acid, tungstic acid, nickel solution, or urea. In some cases, the anodized layer is formed only on the external surface of the metal layer. Accordingly, in these cases, an anodized layer may not be present between the metal layer and the fiber layer.

In some implementations, block 203 may include anodize ion post processing steps. For example, block 203 may include dying the anodized layer. Block 203 may also include sealing the anodized layer. For example, the anodized layer may be sealed after being dyed. The sealing may reduce or eliminate pores in the anodized layer. For example, sealing may include immersion in hot deionized water or steam, or impregnation with a sealant such as polytetrafluoroethylene (PTFE), nickel acetate, cobalt acetate, sodium dichromate, or potassium dichromate.

In some block 203 may include performing MAO on the light metal layer. For example, block 203 may comprise immersing the bonded substrate and light metal layer into an electrolyte bath, such as a dilute alkaline solution of potassium hydroxide, sodium silicate, metal phosphate, potassium fluoride, potassium hydroxide, fluorozirconate, sodium hexametaphosphate, sodium fluoride, ferric ammonium oxalate, phosphoric acid salt, graphite powder, silicon dioxide powder, aluminium oxide powder or polyethylene oxide alkylphenolic ether. Block 203 may further comprising connecting the light metal layer as one electrode in an electrochemical cell and applying a potential to between the electrodes of the cell. For example, the potential may be in the range of 200-600 V, and may be applied as continuous pulsed direct current (DC) or alternating current (AC).

The example method may further include block 204. For example, the example method may include block 204 if the substrate comprises a fiber layer and the final substrate will be a CFRP. Block 204 may include applying a binder to the fiber layer. In some implementations, applying the binder may include infiltrating the binder into the fiber layer. For example, the binder may include a binding polymer, such as a binding polymer of the type described with respect to fiber layer 101 of FIG. 1. In some implementations, block 204 may include applying the binder to the fiber layer by applying a thermoplastic resin film to a side of the fiber layer opposite the metal layer, and heating the thermoplastic resin film to infiltrate the fiber layer. In other implementations, block 204 may include applying the binding polymer to the fiber layer by infiltrating a curable resin into the fiber layer from a side opposite the metal layer and curing the curable resin. For example, the curable resin may comprise a thermosetting resin or a UV curable resin. In some implementations, block 204 is performed after block 203. In these implementations, applying the binder to the fiber may enhance the bond between the metal layer and the fiber layer. For example, during the application, the binder may infiltrate to the interface between the metal layer and the fiber layer.

In some implementations, the example method may include block 205. Block 205 may include coating the oxidized layer. For example, block 205 may include painting, spray coating, dying, laminating, CVD, PVD, electrophoretic deposition, or other coating technologies. The resultant coating may be as described with respect to coating 104 of FIG. 1. For example, the example method may include block 205 if block 203 includes oxidizing the light metal layer using MAO. In a particular implementation, block 205 may include coloring the material by coating the oxidized layer.

In the foregoing description, numerous details are set forth to provide an understanding of the subject disclosed herein. However, implementations may be practiced without some or all of these details. Other implementations may include modifications and variations from the details discussed above. It is intended that the appended claims cover such modifications and variations.

1. A material, comprising:
a substrate comprising a fiber material and a thermoplastic binding polymer;
a light metal layer on the substrate;
an oxidized layer on the light metal layer.

2. The material of claim 1, wherein the oxidized layer comprises an anodized layer.

3. The material of claim 1, wherein the oxidized layer comprises a micro-arc oxidized layer.

4. The material of claim 3, further comprising a coating on the oxidized layer.

5. The material of claim 1, wherein the material constitutes an electronics housing.

6. A material, comprising:
a substrate comprising a light metal and a fiber material;
a second light metal comprising a layer on the substrate;
an oxidized layer.

7. The material of claim 6, wherein the oxidized layer comprises an anodized layer.

8. The material of claim 6, wherein the oxidized layer comprises a micro-arc oxidized layer.

9. The material of claim 6, wherein the material constitutes an electronics housing.

10. A method, comprising:
depositing a light metal layer on a substrate using physical vapor deposition;
oxidizing the light metal layer to form an oxidized layer on the light metal layer.

11. The method of 10, wherein the substrate comprises carbon fiber.

12. The method of claim 11, further comprising:
applying a binder to the substrate opposite the oxidized layer; and
infiltrating the substrate with the binder to form a carbon fiber reinforced plastic.

13. The method of claim 10, wherein the substrate comprises a second light metal.

14. The method of claim 10, wherein the substrate comprises a light metal infiltrated carbon fiber substrate.

15. The method of claim 5, further comprising oxidizing the light metal layer by micro-arc oxidation.

16. The method of claim 5, further comprising oxidizing the light metal layer by anodization.

17. The method of claim 11, further comprising coating the oxidized layer.
